(19) United States
(12) Patent Application Publication
(10) Pub. No.: US 2009/0038241 A1
(43) Pub. Date: Feb. 12, 2009

(54) SOLAR ROOF AND SOLAR BUILDING HAVING SAME

(75) Inventor: GA-LANE CHEN, Santa Clara, CA (US)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Taipei Hsien (TW)

(21) Appl. No.: 12/039,022

(22) Filed: Feb. 28, 2008

(30) Foreign Application Priority Data
Aug. 10, 2007 (CN) 200710201332.6

(51) Int. Cl. E04D 13/18; H01L 31/042

(52) U.S. Cl. 52/173.3; 136/244

(57) ABSTRACT

An exemplary solar roof includes a roof body and a flexible solar cell layer covering the roof body. A surface of the solar cell layer for receiving sun rays forms at least one part of an exterior surface of a dome. The solar cell layer includes a flexible substrate formed on the roof body, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

### CROSS-REFERENCE TO RELATED APPLICATIONS

This application is related to these commonly-assigned copending applications as below: Ser. No. 11/967,008, entitled “SOLAR CELL WITH FLEXIBLE SUBSTRATE” (attorney docket number US 14906); Ser. No. 11/967,009, entitled “SOLAR CELL WITH FLEXIBLE SUBSTRATE” (attorney docket number US 14910); and Ser. No. 11/933,941, entitled “FLEXIBLE SOLAR CELL” (attorney docket number US 15052). Disclosures of the above-identified applications are incorporated herein by reference.

### BACKGROUND

1. Technical Field

The present invention relates to a building with an energy collecting device and, particularly, to buildings with solar cells formed thereon.

2. Description of Related Art

A solar cell is a device that converts light energy into electrical energy. The solar cell is a clean energy power supply source. Nowadays, solar cells are widely used in buildings. Such buildings are called solar buildings.

Generally, solar cells are positioned on a roof of the solar building. Such solar cells can only absorb sun rays coming in from one direction. However, the position of the sun changes throughout the day. Thus, the solar cells can only receive a limited amount of solar energy throughout the day. Therefore, an efficiency of the solar building is low.

Therefore, a new solar building is desired to overcome the above described shortcomings.

### SUMMARY

An exemplary solar roof includes a roof body and a flexible solar cell layer covering the roof body. A surface of the solar cell layer for receiving sun rays forms at least one part of an exterior surface of a dome. The solar cell layer includes a flexible substrate formed on the roof body, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

An exemplary solar building includes a solar roof and a main body supporting the solar roof. The solar roof includes a roof body and a flexible solar cell layer covering the roof body. A surface of the solar cell layer for receiving sun rays forms at least one part of an exterior surface of a dome. The solar cell layer includes a flexible substrate formed on the roof body, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, perspective view of a solar building, together with the sun in winter according to a first embodiment.

FIG. 2 is a schematic, perspective view of the solar building of FIG. 1, together with the sun in summer.

FIG. 3 is a schematic, exploded view of the solar building of FIG. 1.

FIG. 4 is a schematic circuit diagram of the solar building of FIG. 1.

FIG. 5 is a schematic, cross-sectional view of a solar cell of FIG. 1 in an original state (i.e., before being bent or flexed).

FIG. 6 is a schematic, perspective view of a solar building according to a second embodiment.

### DETAILED DESCRIPTION OF THE EMBODIMENTS

Embodiments will now be described in detail below with reference to the drawings.

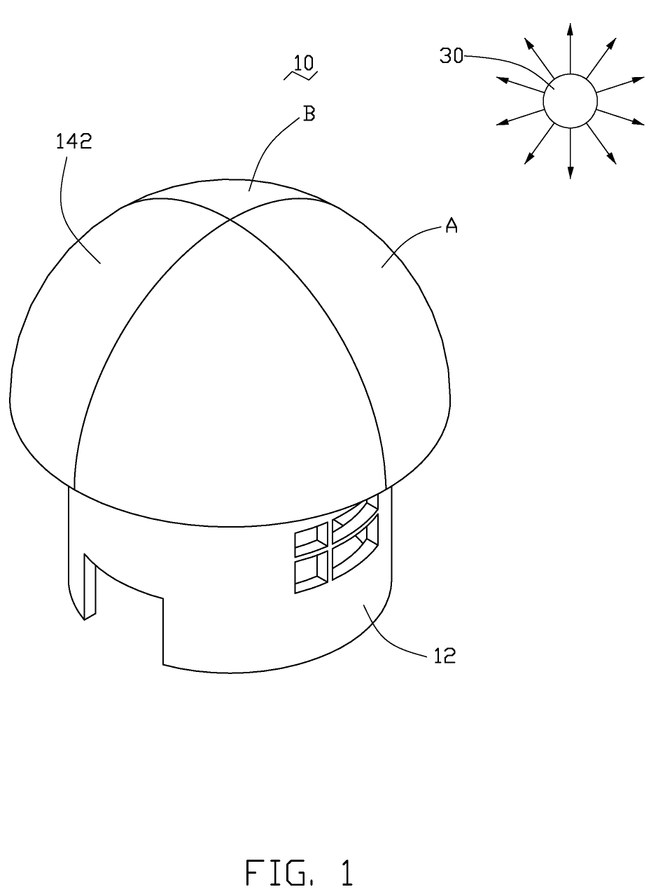

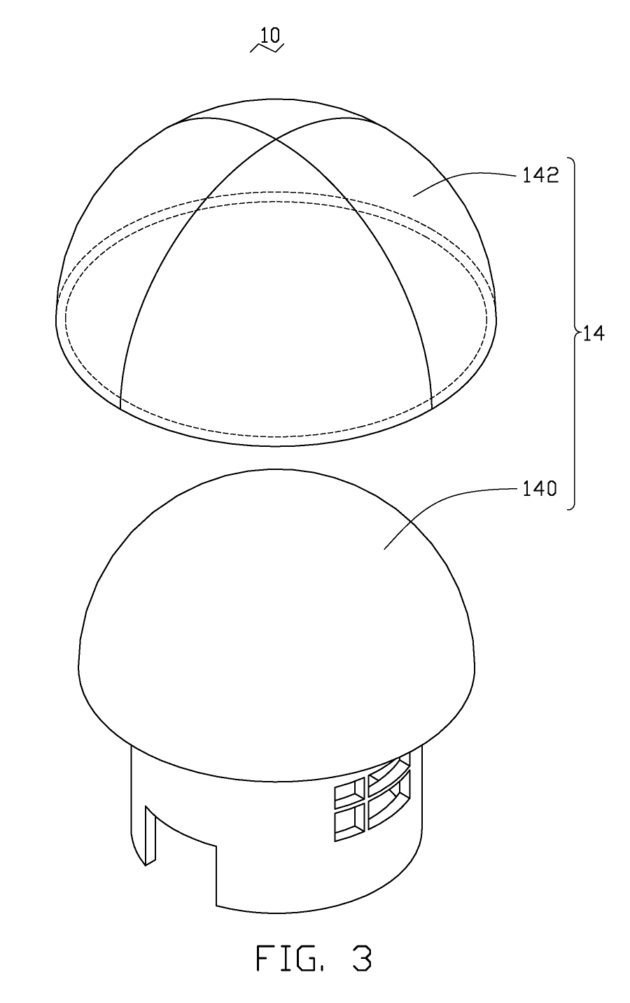

Referring to FIGS. 1 to 3, a solar building 10 of a first embodiment is shown. The solar building 10 includes a main body 12 and a solar roof 14. The main body 12 is configured (i.e., structured and arranged) for supporting the solar roof 14. The solar roof 14 includes a roof body 140 and a flexible solar cell layer (i.e., four flexible solar cells 142) covering the roof body 140.

The roof body 140 has a dome shape. The solar cells 142 are fixedly mounted/positioned on the roof body 140 via, e.g., an adhesive, or a mechanical fastener. The solar cells 142 are in contact with the roof body 140 and, accordingly, positioned along an exterior surface of the dome. Thus, a surface (not labeled) of the solar cells 142 for receiving sun rays forms one part of an exterior surface of a dome. The dome can be a spherical dome or a spheroidal dome. That is, when the dome is a spherical dome, its shape is consistent with being a portion of a sphere. Similarly, the spheroidal dome is consistent in shape with a part of an ellipsoid. In the present embodiment, the dome is spherical and in fact forms a hemisphere.

The roof body 140 can be made of fiber glass (i.e., glass reinforced plastic), glass, or reinforced concrete. The main body 12 can be a cylinder, or a cuboid. In the present embodiment, the main body 12 is a cylinder. The main body 12 can be made of reinforced concrete.

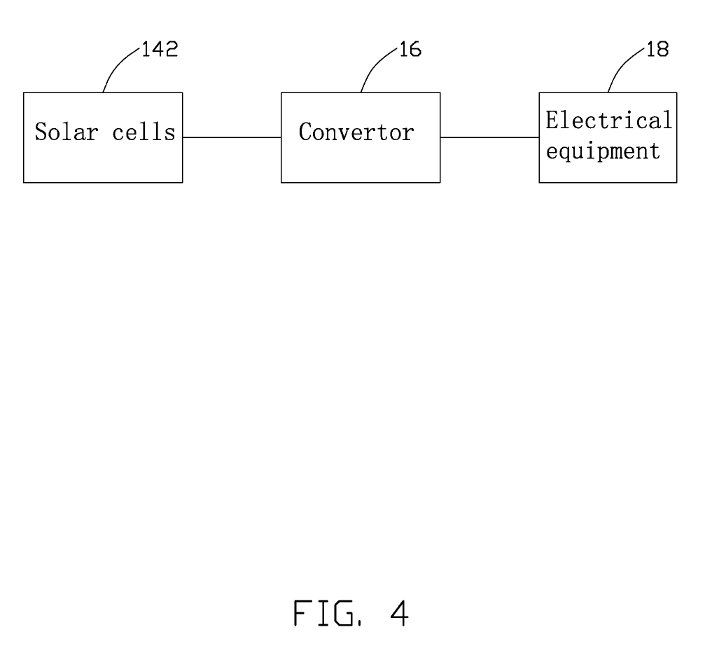

The solar cells 142 are configured for receiving sun rays and converting energy of the sun rays into electrical energy. Referring to FIG. 4, the solar cells 142 can be electrically connected with a converter 16, and then the converter 16 can be electrically connected with an electrical device 18 (e.g., an illumination device). In this way, the solar cells 142 provide electricity to the electrical device.

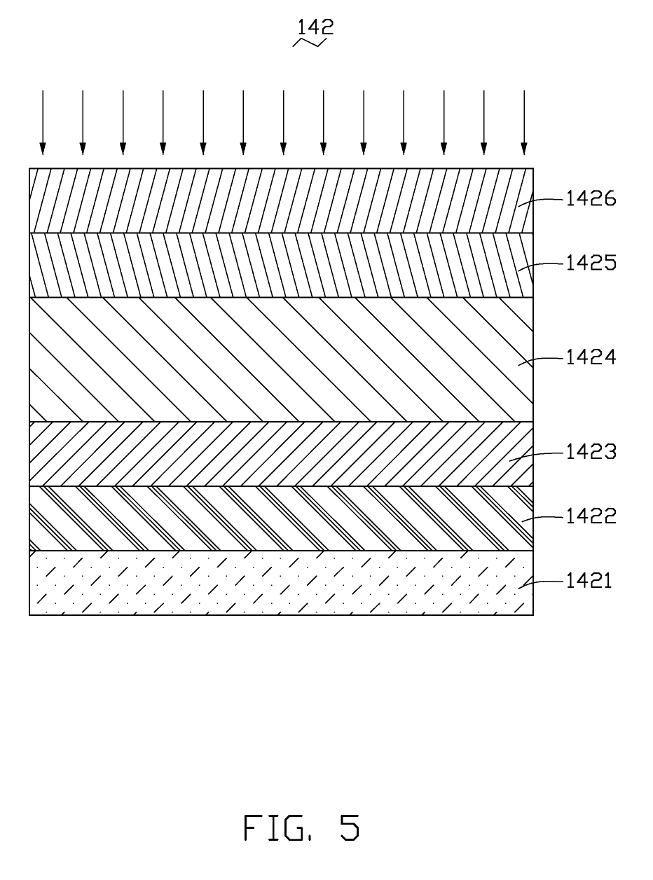

Referring to FIG. 5, a cross-sectional view of the solar cell 142 in an original state (i.e., before being bent or flexed) is shown. The solar cell 142 includes a flexible substrate 1421 formed on the roof body 140. A back metal contact layer 1422, a P-type semiconductor layer 1423, a P-N junction layer 1424, an N-type semiconductor layer 1425, and a front metal contact layer 14266 are formed on the substrate 101 in the order.

The substrate 1421 can be made of stainless steel, aluminum magnesium alloy, or polymer. The stainless steel can be, but is not limited to, austenitic stainless steel, ferritic stainless steel, or martensitic stainless steel. The polymer can be transparent or opaque. The transparent polymer can be, but is not limited to, polycarbonate (PC), or polymethyl methacrylate (PMMA). The opaque polymer can be, but is not limited to, polyether ether ketone (PEEK), or liquid crystal polymer (LCP). A thickness of the substrate 1421 can be in an approximate range from 10 microns to 100 microns.

The back metal contact layer 1422 can be made of silver, copper, molybdenum, aluminum, copper aluminum alloy, silver copper alloy, or copper molybdenum alloy. The back metal contact layer 102 can be formed on the substrate 101 by sputtering or deposition.

The P-type semiconductor layer 1423 can be made of P-type amorphous silicon (P-a-Si), particularly, P-type amorphous silicon with hydrogen (P-a-Si:H). Also, the P-type semiconductor layer 103 can be made of III-V group compound semiconductors or II-VI group compound semiconductors, particularly above semiconductors doped with aluminum, gallium, or indium, e.g., aluminum gallium nitride (AlGaN), aluminum gallium arsenide (AlGaAs).

The P-N junction layer 1424 can be made of III-V or I-III-VI group compound semiconductors, e.g., cadmium telluride (CdTe), copper indium diselenide (CuInSe₂, CIS). Also, The P-N junction layer 104 can be made of copper indium gallium diselenide (CuIn₁₋ₓGaSe₂, CIGS). The P-N junction layer 104 can be formed on the P-type semiconductor layer using chemical vapor deposition or sputtering.

The N-type semiconductor layer 1425 can be made of N-type amorphous silicon (N-a-Si), particularly, N-type amorphous silicon with hydrogen (N-a-Si:H). Also, the N-type semiconductor layer 105 can be made of III-V group compound semiconductors or II-VI group compound semiconductors, particularly above semiconductors doped with nitrogen, phosphorus, arsenic, e.g., gallium nitride (GaN), indium gallium phosphide (InGaP).

The front metal contact layer 1426 can be made of transparent conductive oxide, e.g., indium tin oxide (ITO) or zinc oxide.

In order to improve waterproofing of the solar cell 142, a protective layer (not shown) can be formed on the front metal contact layer 1426. The protective layer can be made of resin.

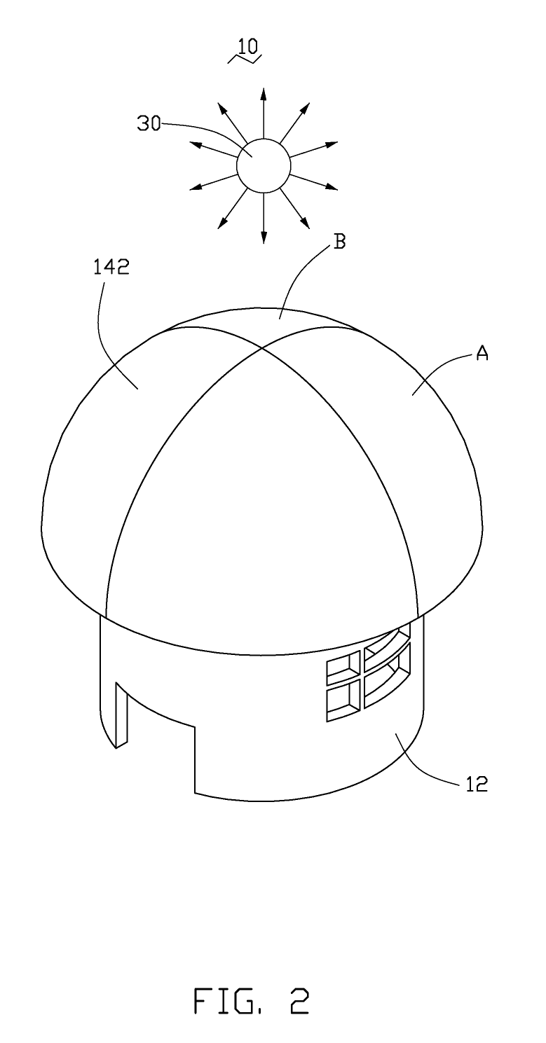

In the solar building 10 of the present embodiment, the solar cells 142 are positioned along the outer surface of a dome. The dome is symmetrical since the dome has an axis of rotation. Accordingly, the solar cells 142 are capable of absorbing sun rays regardless of a position of the sun 30 in the sky. Therefore, an efficiency of the solar building 10 is increased. In more detail, all throughout any given day in any season, the solar cells 142 are capable of absorbing sun rays. For example, at a particular time of a day in winter, the sun 30 is in a first position of the sky, and mainly illuminates area “A” of the solar cells 142, as seen in FIG. 1. Referring to FIG. 2, in summer at the same time of day as in FIG. 1, the sun 30 is in a second position of the sky, and mainly illuminates area “B” of the solar cells 142. Furthermore, when the solar cells 142 are positioned along the outer surface of a hemispherical dome, at any given time when the sun is up, some area of the solar cells 142 is perpendicular to the incoming sun rays. Thus, the efficiency of the solar building 10 is further increased.

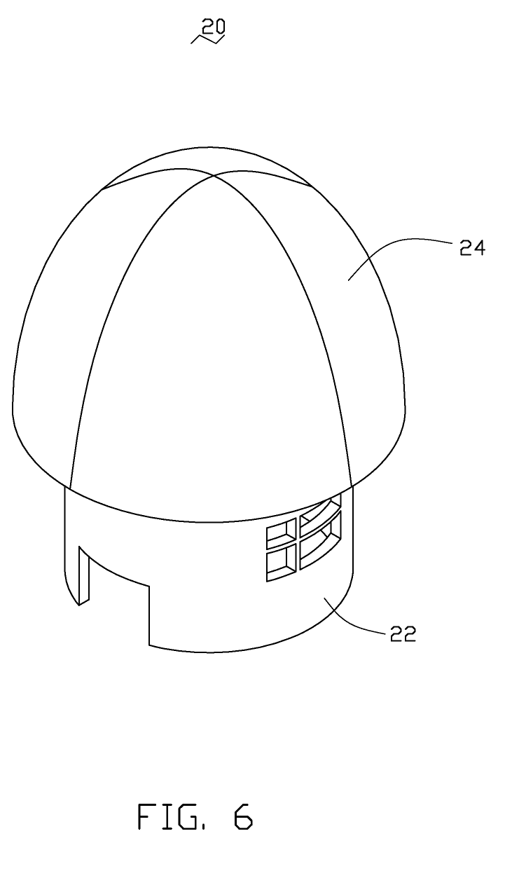

Referring to FIG. 6, a solar building 20 according to a second embodiment is shown. Similar to the solar building 10, the solar building 20 includes a main body 22 and a solar roof 24. The solar roof 24 includes a roof body (not labeled) and solar cells (not labeled) fixedly mounted/positioned on the roof body. The roof body is a semi-ellipsoidal dome. Thus, the solar cells are positioned along an outer surface of the semi-ellipsoidal dome.

It should be noted that the solar cells (not shown) can be further fixedly mounted on a peripheral surface of the main body 22. In this way, more solar energy is collected by the solar cells, and converted into electrical energy.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A solar roof, comprising:
a roof body; and
a flexible solar cell layer covering the roof body, a surface of the solar cell layer for receiving sun rays forming at least a part of an exterior surface of a dome, the solar cell layer comprising:
a flexible substrate formed on the roof body;
a back metal contact layer formed on the substrate;
a P-type semiconductor layer formed on the back metal contact layer;
a P-N junction layer formed on the P-type semiconductor layer;
an N-type semiconductor layer formed on the P-N junction layer; and
a front metal contact layer formed on the N-type semiconductor layer.

2. The solar roof as claimed in claim 1, wherein the dome is one of a spherical dome and a spheroidal dome.

3. The solar roof as claimed in claim 2, wherein the spherical dome is a hemisphere dome.

4. The solar roof as claimed in claim 2, wherein the spheroidal dome is an ellipsoidal dome.

5. The solar roof as claimed in claim 2, wherein the spheroidal dome is a semi-ellipsoidal dome.

6. The solar roof as claimed in claim 1, wherein the roof body is comprised of glass or glass fiber.

7. The solar roof as claimed in claim 1, wherein the substrate is comprised of stainless steel, aluminum magnesium alloy, or polymer.

8. The solar roof as claimed in claim 1, wherein the stainless steel is selected from the group consisting of Austenitic stainless steel, Ferritic stainless steel, or Martensitic stainless steel.

9. The solar roof as claimed in claim 1, wherein the solar cell layer forms at least one part of a dome wall of the dome.

10. A solar building comprising:
a solar roof comprising:
a roof body; and
a flexible solar cell layer covering the roof body, a surface of the solar cell layer for receiving sun rays forming at least a part of an exterior surface of a dome, the solar cell layer comprising a flexible substrate formed on the roof body, a back metal contact layer formed on the substrate, a P-type semiconductor layer formed on the back metal contact layer, a P-N junction layer formed on the P-type semiconductor layer, an N-type semiconductor layer formed on the P-N junction layer, and a front metal contact layer formed on the N-type semiconductor layer; and
a main body supporting the solar roof thereon.

11. The solar building as claimed in claim 10, wherein the dome is one of a spherical dome and a spheroidal dome.

12. The solar building as claimed in claim 11, wherein the spherical dome is a hemisphere dome.

13. The solar building as claimed in claim 11, wherein the spheroidal dome is an ellipsoidal dome.

14. The solar building as claimed in claim 11, wherein the spheroidal dome is a semi-ellipsoidal dome.

15. The solar building as claimed in claim 10, wherein the roof body is comprised of glass or glass fiber.

16. The solar building as claimed in claim 10, wherein the substrate is comprised of stainless steel, aluminum magnesium alloy, or polymer.

17. The solar building as claimed in claim 1, wherein the solar cell layer forms at least one part of a dome wall of the dome.
